(19) United States
(12) Patent Application Publication
(10) Pub. No.: US 2005/0180245 A1
(43) Pub. Date: Aug. 18, 2005

(54) Bus-powered transmitter

(76) Inventor: Naoki Maeda, Tokyo (JP)

Correspondence Address: FISH & RICHARDSON P.C., CITIGROUP CENTER 52ND FLOOR, 153 EAST 53RD STREET, NEW YORK, NY, 10022-4611, US

(21) Appl. No.: 11/046,977

(22) Filed: Jan. 31, 2005

(30) Foreign Application Priority Data
Feb. 12, 2004 (JP) P2004-034415

(51) Int. Cl. G11C 5/00

(52) U.S. Cl. 365/226

(57) ABSTRACT

A bus-powered transmitter to which electric power is provided through a communication line, has a memory that stores data, and a CPU that outputs commands, which instruct to write data into the memory and erase data stored in the memory, to the memory. The CPU has an erasure control section that alternately and repeatedly outputs an erasure suspending command which instructs to suspend an erasure of data stored in the memory and an erasure resuming command which instructs to resume the suspended erasure during a period after the erasure is started and before the erasure is completed.

### BACKGROUND OF THE INVENTION

1. Field of the Invention

The invention relates to a bus-powered transmitter that has a memory, into which data is written and from which data is erased according to commands output from a CPU, and that is supplied with driving power from a two-wire communication line.

2. Description of the Related Art

The following document relates to a related art concerning a bus-powered transmitter.

JP-A-2002-354714 is referred to as a related art.

FIG. 4 is a functional block diagram illustrating an example of a conventional two-wire bus-powered transmitter disclosed in JP-A-2002-354714.

In FIG. 4, reference numerals 1 and 2 denote bus connection terminals, to which driving power is supplied from an external device located at a remote position through, for example, a two-wire communication line connected thereto. This bus-powered transmitter communicates with the external device by using digital signals to thereby modulate the value of a supply current. The communication line to which such a bus-powered transmitter is connected is, for instance, “Foundation Fieldbus” and “Profibus”.

Reference numeral 3 denotes a CPU, and reference numeral 4 denotes a communication interface. The communication interface 4 communicates with the CPU 3 through a CPU bus 5. Reference numeral 6 denotes a flash ROM which also communicates with the CPU 3 through the CPU bus 5.

The CPU 3 processes signals inputted from a sensor (not shown) placed in a field. The CPU 3 also transmits signals generated by modulating the supply current Iₒᵤₜ, which is supplied from the transmitter, to the external device through the communication interface 4, and receives signals transmitted from the external device through the communication interface 4 by utilizing change in the voltage V0 at the bus connection terminal 1.

Reference numeral 7 denotes a series regulator that supplies constant voltage V1 to the flash ROM 6.

A transistor Q1 is provided between the bus connection terminal 1 and the series regulator 7 and controls the supply current Iₒᵤₜ. A transistor Q2 is provided between the base of the transistor Q1 and a reference potential point E and controls the base current of the transistor Q1.

An operational amplifier Q3 controls the base potential of the transistor Q2. A resistor R1 is provided between a bus connection terminal 2 and the reference potential point E and generates a voltage that is proportional to the supply current Iₒᵤₜ. The difference between this voltage and a reference voltage Vᵣ is divided by obtaining a feedback voltage V_{f}, which is provided to a non-inverting input terminal of the operational amplifier Q3, through the use of resistors R2 and R3.

A set voltage Vₛ, which is obtained by dividing the reference voltage Vᵣ through the use of resistors R4 and R5, is provided to an inverting input terminal of the operational amplifier Q3. Thus, the supply current Iₒᵤₜ is controlled by a feedback control system, which mainly has the transistors Q1 and Q2 and the operational amplifier Q3, so that the feedback voltage V_{f} is equal to the set voltage Vₛ.

A transmission signal TX sent from the communication interface 4 modulates the supply current Iₒᵤₜ by modulating the feedback voltage V_{f} through a capacitor C1. On the other hand, a transmission signal V0 sent from the external device, which is superposed onto the voltage developed across the bus connection terminals 1 and 2, is provided to the communication interface 4 through a capacitor C2 as a reception signal RX.

Reference character SW denotes a switch that is opened and closed according to a signal CNT outputted from the CPU 3. When the switch SW is closed, a resistor R6 is connected to the voltage dividing resistor R3 in parallel, so that a voltage division ratio is reduced and thus the supply current is increased. This operation of increasing the supply current is performed in a period during data stored in the flash ROM 6 is erased by the CPU 3.

That is, the flash ROM 6 is supplied with power at a voltage V1 generated by the series regulator 7. Usually, the switch SW is opened under the control of the CPU 3 so that the flash ROM 6 operates in a condition where the supply current Iₒᵤₜ is small. However, when data is downloaded into the flash ROM 6 form the external device, the switch SW is closed under the control of the CPU 3 thereby to increase the supply current Iₒᵤₜ and to supply electric current, which is needed for erasing the data from the flash ROM 6.

When software is downloaded from the external device into the flash ROM, an operation to be performed is to write data, which is sent by communication, thereto piece by piece after data stored in the flash ROM is erased in units of sectors or after the entire chip in the flash ROM is erased at one time.

Generally, the magnitudes of erase/write currents for a flash ROM range from 20 mA to 30 mA. As compared the erasing period with the writing period, the writing period per piece of data is several tens μsec and thus short. Therefore, the supply current does not need to be increased even in the case of the related art. However, regarding the erasing period, time needed for the erase thereof ranges several hundreds msec to several sec. Thus, the erase current needs to be increased by an amount of the erase current for the flash ROM.

For example, in the case of the bus-powered transmitter that is compatible with “Foundation Fieldbus,” generally, the supply current supplied during a normal operation ranges from 10 mA to 18 mA. Therefore, when software is downloaded thereinto, the supply current should be set to be double that supplied during a normal operation so as to ensure the erase current for the flash ROM. Thus, the transmitter being connectable to a single power supply located at a remote position is limited, that components to be used therein are expensive, and that the circuit design thereof is difficult.

### SUMMARY OF THE INVENTION

The object of the invention is to provide a bus-powered transmitter that enables to suppress increase in the supply current during the downloading of software.

The invention provides a bus-powered transmitter to which electric power is provided through a communication line, having: a memory that stores data; and a CPU that outputs commands, which instruct to write data into the memory and erase data stored in the memory, to the memory, wherein the CPU has an erasure control section that alternately and repeatedly outputs an erasure suspending command which instructs to suspend an erasure of data stored in the memory and an erasure resuming command which instructs to resume the suspended erasure during a period after the erasure is started and before the erasure is completed.

Furthermore, the erasure control section outputs the erasure suspending command and the erasure resuming command based on a predetermined duty ratio.

The bus-powered transmitter further has a first primary delay circuit provided between a series regulator for supplying the memory with a constant voltage and the memory.

The bus-powered transmitter further has a second primary delay circuit provided between the communication line and the series regulator.

The first primary delay circuit has a resistor and a capacitor.

The second primary delay circuit has a resistor and a capacitor.

The bus-powered transmitter further has a supply current changing section that increases a supply current supplied to the communication line during a period after the erasure of data stored in the memory is started and the erasure is completed.

The CPU has the supply current changing section. Alternatively, an external device comprises the supply current changing section.

According to the bus-powered transmitter, it is possible to perform an erase operation without increasing a supply current thereof to an erase current for erasing data stored in the memory during the erasure of the memory.

Consequently, even in a case where the erase current for the flash ROM is ensured when software is downloaded thereinto, it is unnecessary to increase the supply current to be equal to or more than double that supplied during the normal operation. The limitation to the numbers of the transmitters, which are connectable to the single power supply located at a remote position, is alleviated. Also, the number of components used therein is small, and that the circuit deign thereof is facilitated.

### BRIEF DESCRIPTION OF THE DRAWINGS

FIG. 1 is a functional block diagram illustrating an embodiment of a bus-powered transmitter according to the invention;

FIGS. 2A and 2B are time charts illustrating an erase control operation to be performed by a CPU 100;

FIG. 3 is a functional block diagram illustrating another embodiment of a bus-powered transmitter to which the invention is applied; and

FIG. 4 is a functional block diagram illustrating an example of a conventional two-wire bus-powered transmitter.

### DETAILED DESCRIPTION OF THE PREFERRED EMBODIMENT

A bus-powered transmitter of an embodiment according to the invention is described in detail with reference to the drawings.

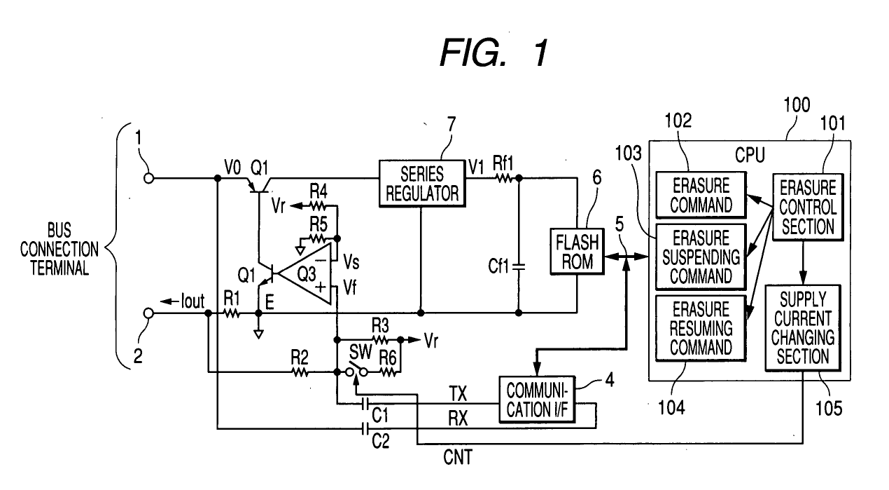

FIG. 1 is a functional block diagram illustrating an embodiment of a bus-powered transmitter according to the invention. In FIG. 1, the components denoted by the same reference numerals of those in the conventional bus-powered transmitter shown in FIG. 4 have the same or similar function, and therefore their description will be omitted. Hereunder, the features of the bus-powered transmitter of the embodiment are described.

Reference numeral 100 in FIG. 1 denotes a CPU in the bus-powered transmitter of the embodiment.

The flash ROM 6 is connected to the CPU 100 through the CPU bus 5. The CPU 100 reads data from the flash ROM 6, writes data into the flash ROM 6, and erases data stored in the flash ROM 6, by providing commands to the flash ROM 6.

Reference numeral 101 denotes an erasure control section provided in the CPU 100. The erasure control section 101 controls the erasing of data stored in the flash ROM 6 by outputting an erase command 102, an erasure suspending command 103, and an erasure resuming command 104 to the flash ROM 6. Those commands are outputted with using a timer function of the erasure control section 101.

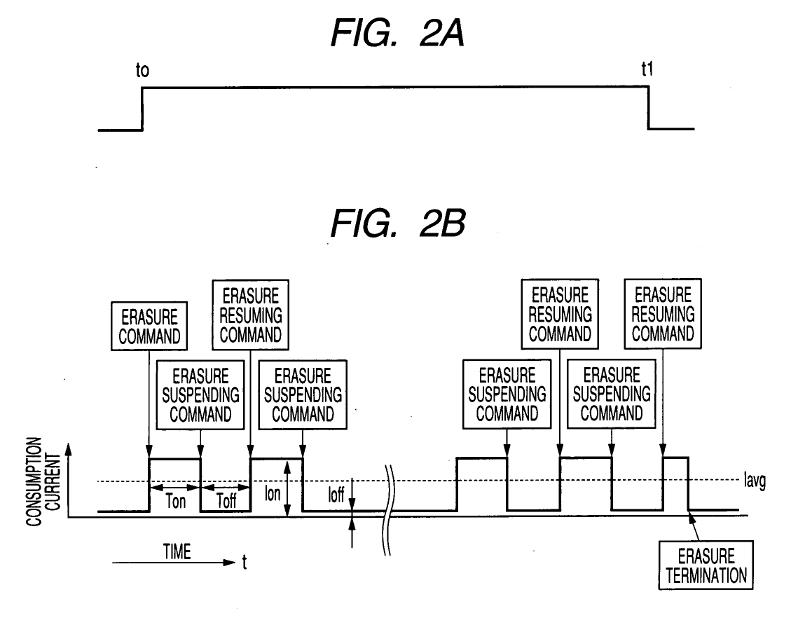

FIGS. 2A and 2B are time charts illustrating an operation of the erasure control section 101.

FIG. 2A illustrates an erasure period from time t0 to time t1, in which the flash ROM is erased. FIG. 2B illustrates control operations performed by using an erasure command, an erasure suspending command, and an erasure resuming commands generated in this erasure period. The operations performed by using these commands are repeated with a predetermined duty ratio.

The consumption current of the flash ROM 6 in the erasure period Tₒₙ from the start/resuming of the erasure to the suspending thereof has a value Iₒₙ. In the case where an erasure suspending command is provided in the erasure period, the consumption current of the flash ROM 6 decreases to a value I_{off}.

When an erasure resuming command is provided after a suspending period T_{off}, the flash ROM 6 resumes the erasure. The value of the consumption current thereof returns to Iₒₙ.

Thus, in the case where the erasure suspending command and the erasure resuming command are alternately and repeatedly outputted during a period after the erasure is started in response to the erasure command, and before the erasure is completed. The consumption current repeats increasing and decreasing in response to the erasure-command/the erasure-resuming command and the erasure suspending command.

Considering the case where the suspending and the resuming of the erasure are repeated at a constant period, an average consumption current I_{avg} in a period from the erasure start to the erasure completion is expressed by the following equation.
I_{avg}=(Tₒₙ*Iₒₙ+T_{off}*I_{off})/(Tₒₙ+T_{off})

Because I_{off}<Iₒₙ, therefore I_{avg}<Iₒₙ. As compared with the case that an erasure operation is performed without repeating the suspension and the resuming of the erasure, the consumption current is reduced. Assuming that the duty ratio is 50%, the value I_{avg} is reduced to half the value Iₒₙ.

Further, a primary delay circuit having a resistor R_{f1} and a capacitor C_{f1} is provided between the series regulator 7 and the flash ROM 6. The capacitor C_{f1} provided in the primary delay circuit supplies an erasure current to the flash ROM 6 during the period Tₒₙ to thereby hold a power supply voltage. The resistor R_{f1} restricts the electric current provided from the input side of the series regulator 7 when the capacitor C_{f1} during the erasure is performed and after the erasure is suspended.

Thus, even when the increment of the supply current Iₒᵤₜ of the transmitter is less than the erasure current for the flash ROM 6, the erasing of the flash ROM 6 is enabled by appropriately determining the values Tₒₙ, T_{off}, C_{f1}, and R_{f1}.

Reference numeral 105 denotes a supply current changing section provided in the CPU 100. The supply current changing section 105 provides a switch SW with a signal CNT for increasing the supply current Iₒᵤₜ during the erasure period of the flash ROM 6. The function of performing the current changing operation is an auxiliary function for the invention and is not indispensable to the invention. Even when the function is utilized, the transmitter of the invention can hold down the increase in the current, as compared with the conventional transmitter.

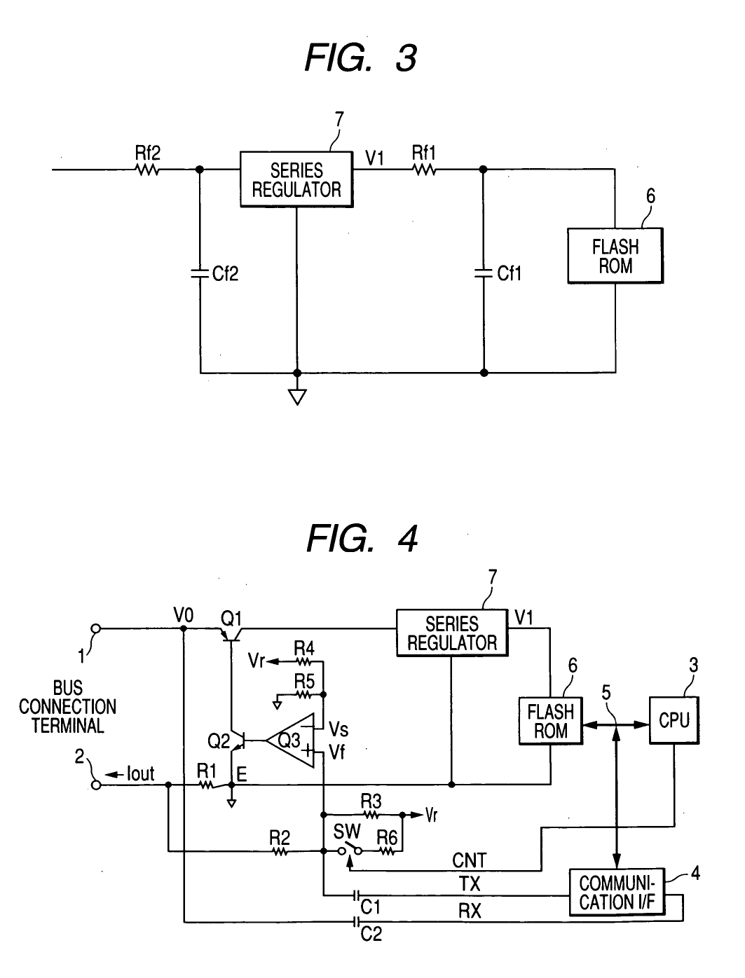

FIG. 3 is a circuit configuration diagram illustrating another embodiment of the bus-powered transmitter. This embodiment is an example of also providing another primary delay circuit, which has a resistor R_{f2} and a capacitor C_{f2} at the input side of the series regulator 7. According to the embodiment, it is possible to further suppress the variation of an input-side voltage of the series regulator 7.

In the above embodiment, the erasure control section 101 is provided in the CPU 100. The erasure control section 101 may be provided in an external device connected to the CPU bus 5 (including the address bus, the data bus, and the control signal bus). In such a case, the external device provides the flash ROM 6 with commands, which relate to the erasure thereof, by communication.

1. A bus-powered transmitter to which electric power is provided through a communication line, comprising:
a memory that stores data; and
a CPU that outputs commands, which instruct to write data into the memory and erase data stored in the memory, to the memory,
wherein the CPU has an erasure control section that alternately and repeatedly outputs an erasure suspending command which instructs to suspend an erasure of data stored in the memory and an erasure resuming command which instructs to resume the suspended erasure during a period after the erasure is started and before the erasure is completed.

2. The bus-powered transmitter according to claim 1,
wherein the erasure control section outputs the erasure suspending command and the erasure resuming command based on a predetermined duty ratio.

3. The bus-powered transmitter according to claim 1, further comprising:
a first primary delay circuit provided between a series regulator for supplying the memory with a constant voltage and the memory.

4. The bus-powered transmitter according to claim 3, further comprising:
a second primary delay circuit provided between the communication line and the series regulator.

5. The bus-powered transmitter according to claim 3,
wherein the first primary delay circuit comprises a resistor and a capacitor.

6. The bus-powered transmitter according to claim 4,
wherein the second primary delay circuit comprises a resistor and a capacitor.

7. The bus-powered transmitter according to claim 1, further comprising:
a supply current changing section that increases a supply current supplied to the communication line during a period after the erasure of data stored in the memory is started and the erasure is completed.

8. The bus-powered transmitter according to claim 7,
wherein the CPU comprises the supply current changing section.

9. The bus-powered transmitter according to claim 7,
wherein an external device comprises the supply current changing section.
